(19) United States
(12) Patent Application Publication
(10) Pub. No.: US 2011/0024048 A1
(43) Pub. Date: Feb. 3, 2011

(54) PLASMA PROCESSING APPARATUS

(75) Inventors: Hideo Nakamura, Hyogo-ken (JP); Jun Yamashita, Hyogo-ken (JP); Junichi Kitagawa, Hyogo-ken (JP); Yoshiro Kabe, Hyogo-ken (JP); Yoshinori Fukuda, Hyogo-ken (JP)

Correspondence Address: SMITH, GAMBRELL & RUSSELL, 1130 CONNECTICUT AVENUE, N.W., SUITE 1130, WASHINGTON, DC, 20036, US

(73) Assignee: Tokyo Electron Limited, Tokyo-To (JP)

(21) Appl. No.: 12/935,392

(22) PCT Filed: Mar. 31, 2009
(86) PCT No.: PCT/JP2009/056679

§ 371 Date: Sep. 29, 2010

(30) Foreign Application Priority Data
Mar. 31, 2008 (JP) 2008-092423
Sep. 30, 2008 (JP) 2008-253930

(51) Int. Cl. H01L 21/306; C23F 1/08; C23C 16/00

(52) U.S. Cl. 156/345.51; 118/723 R

(57) ABSTRACT

In a plasma oxidation processing apparatus (100) which supplies a high-frequency bias power to an electrode (7) embedded in a stage (5), the interior surface, which is to be exposed to a plasma, of an aluminum lid (27) which functions as an opposite electrode for the stage (5) is coated with a silicon film (48) as a protective film. Positioned adjacent to the silicon film (48), an upper liner (49a) and a thicker lower liner (49b) are provided on the interior surfaces of a second container (3) and a first container (2). This prevents a short circuit or abnormal electrical discharge to the interior surfaces, making it possible to form a proper high-frequency current path and enhance the efficiency of power consumption.

### TECHNICAL FIELD

The present invention relates to a plasma processing apparatus for performing plasma processing of a processing object, such as a semiconductor wafer.

### BACKGROUND ART

In a semiconductor device manufacturing process, various types of processing, such as etching, ashing, film-forming processing, etc., are performed on a semiconductor wafer as a processing object. For such processing is used a plasma processing apparatus which performs plasma processing of a semiconductor wafer in a processing container which can be kept in a vacuum atmosphere. In the plasma processing apparatus, the interior wall of the processing container is formed of a metal such as aluminum. Therefore, the interior wall surface, when exposed to a strong plasma, can be eroded by the plasma, resulting in the generation of particles. The particles will cause contamination of a processing object with the metal, such as aluminum, which adversely affects a device.

In order to solve the problem, a technique has been proposed which, in an RASA microwave plasma-type plasma processing apparatus which introduces microwaves into a processing container by means of a plane antenna to generate a plasma, involves coating with silicon an area which is to be exposed to a plasma in the processing container (see e.g. Japanese Patent Laid-Open Publication No. 2007-250569).

Responding to the recent progress toward larger-sized semiconductor wafers and finer devices, there is a demand for improvements in the efficiency (e.g. film-forming rate) of plasma processing and in the uniformity of processing (uniformity of film thickness) in wafer surface. From this viewpoint, also in a film-forming process as typified by plasma oxidation processing, attention has been drawn to a method in which plasma processing of a semiconductor wafer is carried out while applying a bias to the semiconductor wafer by supplying a high-frequency power to an electrode embedded in a stage, on which the semiconductor wafer is placed, in a processing container of a plasma processing apparatus.

To supply a high-frequency power to the electrode of the stage, it is necessary to provide in the processing container an electrode (opposite electrode) disposed on the opposite side of a plasma processing space from the electrode of the stage. A conductive metal is desirable as a material for the opposite electrode. In a plasma oxidation process, however, a plasma having a strong oxidizing effect is generated in the vicinity of the opposite electrode, whereby the surface of the opposite electrode is oxidized and deteriorated, which can cause the generation of particles and metal contamination. To deal with the problem, the surface of the opposite electrode may be coated with a metal oxide, such alumina or yttria, to enhance the durability of the electrode. The metal oxide coating on the opposite electrode, because of its high resistivity and dielectric constant, has excellent insulating properties. The metal oxide coating, however, entails the following problems: The surface potential of the coated opposite electrode rises as a plasma is generated, which produces a large potential difference between the opposite electrode and the plasma, leading to the formation of a sheath. The coating surface is therefore susceptible to the sputtering action of the plasma, leading to the progress of deterioration of the coating. In order to reduce sputtering of the opposite electrode, it is preferred to increase the area of the opposite electrode compared to the lower electrode. This, however, increases the plasma contact area of the opposite electrode, leading to higher possibility of metal contamination. Further, in an RLSA microwave plasma-type plasma processing apparatus as disclosed in the JP 2007-250569 document, a microwave introduction section is disposed over a processing container. Thus, unlike a plasma processing apparatus such as of the parallel plate type, it is difficult for an RLSA microwave plasma-type apparatus to use an opposite electrode having a large area also because of the restrictions of the apparatus construction.

In general, when a high-frequency bias power is supplied to the electrode embedded in the stage, a high-frequency current path (RF return circuit) is formed which runs from the stage to the opposite electrode via a plasma processing space, and returns from the opposite electrode to the earth of a high-frequency bias power source via the wall of the processing container, etc. If the high-frequency current path is not formed stably, the efficiency of the consumption of the high-frequency power will be low. A short circuit or an abnormal electrical discharge, if it occurs in the high-frequency current path, causes problems such as a lowering of the process efficiency, an unstable process, etc. For example, if a short circuit occurs whereby a high-frequency current, which is to flow from the stage to the opposite electrode via a plasma processing space, flows from the stage e.g. to the side wall, lying nearer to the stage than the opposite electrode, of the processing container, there will be a lowering of the consumption efficiency of the high-frequency power and a lowering of the process efficiency. In the case where the opposite electrode is coated with a metal oxide in order to prevent damage to the opposite electrode, the surface potential of the coating is likely to rise as described above. The coating is therefore susceptible to the sputtering action of a plasma and, in addition, an abnormal electrical discharge is likely to occur in the coating area.

### SUMMARY OF THE INVENTION

The present invention has been made in view of the above situation. It is therefore an object of the present invention to provide a plasma processing apparatus of the type that supplies a high-frequency bias power to an electrode of a stage for placing a processing object on it, which makes it possible to optimize a high-frequency current path and thereby increase the power consumption efficiency, and to prevent an abnormal electrical discharge, thus enabling a highly efficient process.

The plasma processing apparatus of the present invention includes: a processing container, having an opening at a top thereof, for processing a processing object by using a plasma; a gas introduction part that supplies a processing gas into the processing container; an exhaust device that depressurizes and evacuates the processing container; a stage, for placing the processing object thereon, disposed in the processing container; a first electrode, embedded in the stage, for applying a bias to the processing object; a second electrode comprising a conductive member and formed at a location across plasma processing space from the first electrode, at least part of the second electrode facing a plasma generation space in the processing chamber; a dielectric plate transmissive to microwaves, supported by the second electrode and closing the opening of the processing chamber; and a plane antenna, provided over the dielectric plate, for introducing microwaves into the processing chamber, wherein a protective film is formed on a surface of the portion, facing the plasma generation space, of the second electrode, the protective film being made by coating the surface with a silicon film, and wherein a first insulating plate is provided along an upper portion of an interior wall of the processing container, and a second insulating plate is provided adjacent to the first insulating plate and along a lower portion of the interior wall of the processing container.

In the plasma processing apparatus of the present invention, the thickness of the second insulating plate is preferably larger than the thickness of the first insulating film.

In the plasma processing apparatus of the present invention, the second insulating plate preferably covers at least part of that area of the interior wall of the processing container which lies lower than the stage in which the first electrode is embedded. In this case, the lower end of the second insulating plate preferably lies in an exhaust chamber provided continuously with the bottom of the processing container.

Preferably, in the plasma processing apparatus of the present invention, the processing container includes a first container and a second container joined to the upper end surface of the first container; a gas passage for the processing gas, coming from a gas supply mechanism and to be supplied into the processing container, is formed between the first container and the second container; an inner first sealing member and an outer second sealing member are provided doubly on both sides of the gas passage; and the first container is in contact with the second container in an inner joint area, lying on the inner side of the processing container, where the first sealing member is provided, whereas a gap is formed between the first container and the second container in an outer joint area, lying on the outer side of the processing container, where the second sealing member is provided. In this case, the gas passage is preferably formed by a step provided in the upper end surface of the first container and by a step provided in the lower end surface of the second container.

Preferably, the plasma processing apparatus of the present invention is constructed as a plasma oxidation processing apparatus for performing plasma oxidation processing of the processing object; and the protective silicon film has been oxidized by the oxidizing action of the plasma and modified into a silicon dioxide film.

In the plasma processing apparatus of the present invention, the dielectric plate, the first insulating plate and the second insulating plate are preferably made of quartz.

According to the plasma processing apparatus of the present invention, a protective silicon film is provided on the surface of the second electrode (opposite electrode) facing the stage electrode to which a high-frequency bias power is supplied. Further, the first insulating plate is provided adjacent to the protective film, and the second insulating plate is provided continuously with the first insulating plate. The protective silicon coating film, because of silicon having electrical conductivity, facilitates the formation of a proper high-frequency current path that runs from the stage to the second electrode via a plasma processing space, thereby preventing a short circuit or an abnormal electrical discharge at other sites, and also has the effect of protecting the surface of the metallic second electrode and enhancing its durability. Furthermore, the silicon of the protective film, when oxidized, turns into silicon dioxide having a small product of the dielectric constant and the resistivity. Therefore, the oxidized protective film shows only a small rise in the surface potential and is little susceptible to the sputtering action of a plasma and, in addition, is unlikely to cause an abnormal electrical discharge because of the low surface potential, thus enabling a long-term protection of the second electrode from a plasma.

A high-frequency current, which has flowed to the second electrode, flows down the side wall of the processing container and is introduced into a lower portion of the processing container. Because an abnormal electrical discharge from the stage directly to the side wall of the processing container is prevented by the first insulating plate and the second insulating plate, a proper high-frequency current path can be maintained. It thus becomes possible to improve the power consumption efficiency of a high-frequency bias power and to carry out plasma processing stably while avoiding the adverse effect of abnormal electrical discharge on processing.

### BRIEF DESCRIPTION OF THE DRAWINGS

FIG. 1 is a schematic cross-sectional view of a plasma oxidation processing apparatus according to an embodiment of the present invention;

FIG. 2 is an enlarged cross-sectional view of a main portion of FIG. 1;

FIG. 3 is a diagram showing the structure of a plane antenna;

FIG. 4 is a diagram illustrating the construction of a control section;

FIG. 5 is a diagram illustrating the flow of electric current in the plasma oxidation processing apparatus;

FIG. 6 is a diagram illustrating an equivalent circuit of an RF return circuit;

FIG. 7 is a graph showing the results of measurement of aluminum contamination and the number of particles in plasma oxidation processing; and

FIG. 8 is a graph showing the results of measurement of the high-frequency power dependency of the oxidation rate and its uniformity in wafer surface in plasma oxidation processing.

### BEST MODE FOR CARRYING OUT THE INVENTION

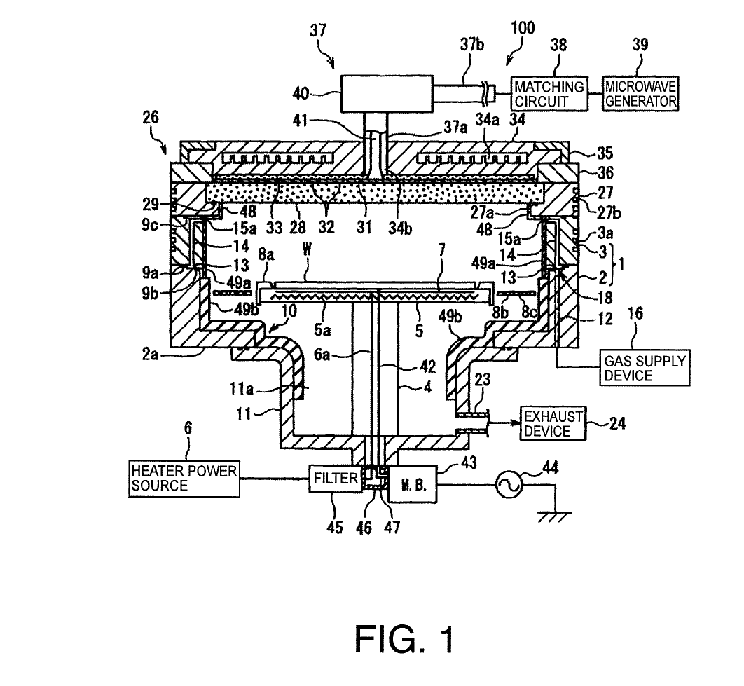

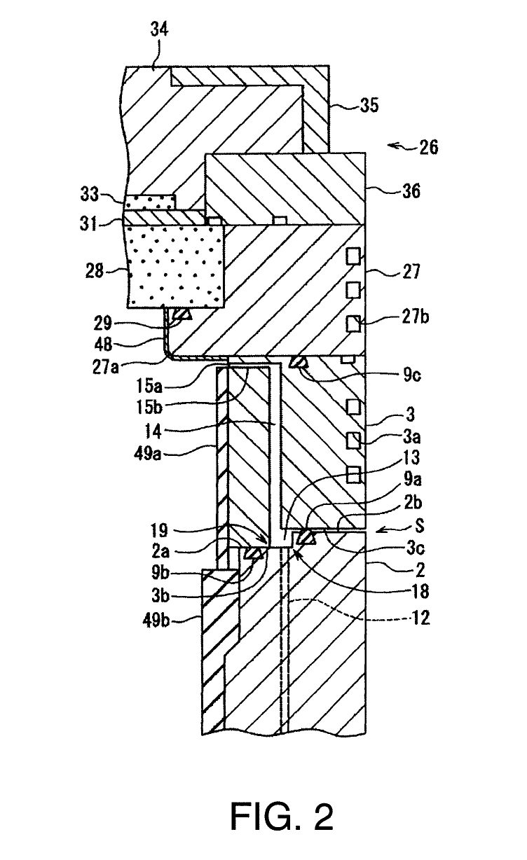

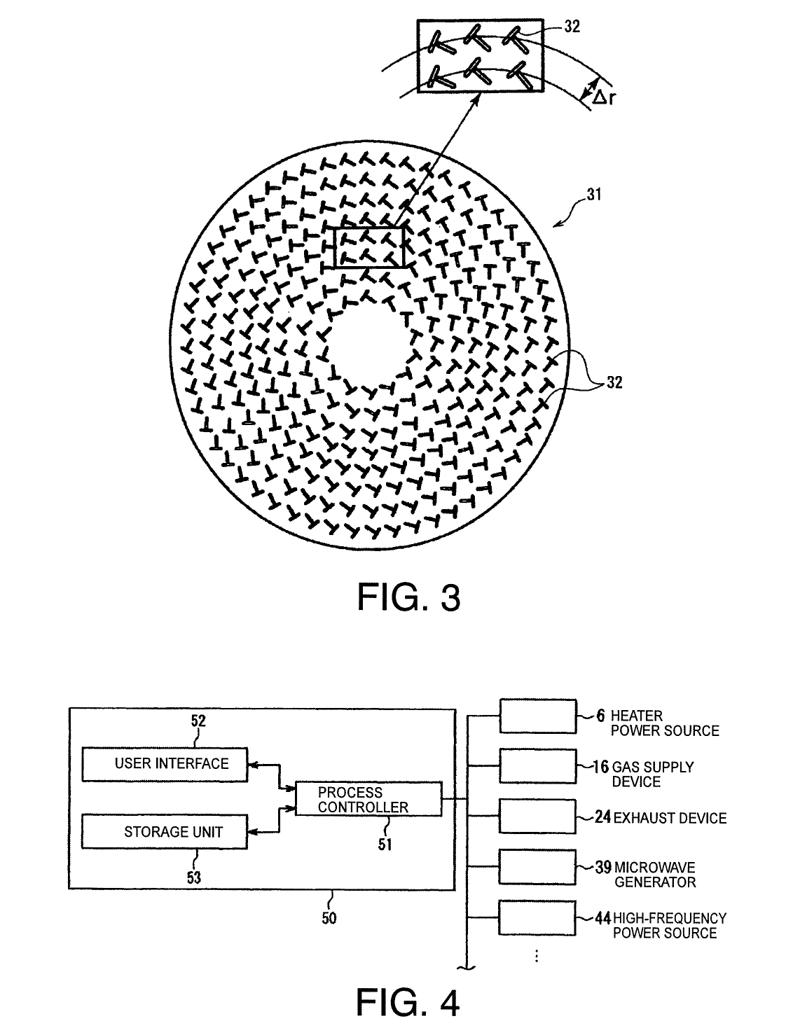

Preferred embodiments of the present invention will now be described in detail with reference to the drawings. FIG. 1 is a cross-sectional view schematically showing the construction of a plasma oxidation processing apparatus 100 according to an embodiment of the plasma processing apparatus of the present invention. FIG. 2 is an enlarged cross-sectional view of a main portion of FIG. 1. FIG. 3 is a plan view showing the plane antenna of the plasma oxidation processing apparatus 100 of FIG. 1.

The plasma oxidation processing apparatus 100 is constructed as an RLSA microwave plasma processing apparatus capable of generating a high-density, low-electron temperature, microwave-excited plasma by introducing microwaves directly into a processing chamber by means of a plane antenna having a plurality of slot-like holes, in particular an RLSA (radial line slot antenna). The plasma oxidation processing apparatus 100 can perform processing with a plasma having a plasma density of 1×10¹⁰ to 5×10¹²/cm³ and a low electron temperature of 0.7 to 2 eV. The plasma oxidation processing apparatus 100 can therefore be advantageously used in the manufacturing of a variety of semiconductor devices, for example to form a silicon oxide film (e.g. SiO₂ film) by oxidizing a silicon surface of a processing object.

The plasma oxidation processing apparatus 100 includes a generally-cylindrical airtight and grounded processing container 1 into which a semiconductor wafer (hereinafter simply referred to as “wafer”) is to be carried. The processing container 1 is made of a metal material, such as aluminum or its alloy, or stainless steel, and is comprised of a first container 2, constituting the lower part of the processing container 1 and having a first inner wall portion, and a second container 3 disposed on the first container 2 and having a second inner wall portion. The first container 2 and the second container 3 may be formed integrally. A microwave introduction section 26 for introducing microwaves into a processing space is provided on the processing container 1 to open and close it. Thus, the microwave introduction section 26 engages the upper end of the second container 3, and the lower end of the second container 3 is joined to the upper end of the first container 2. A plurality of cooling water flow passages 3a are formed in the second container 3 so that the wall of the second container 3 can be cooled. This can prevent positional displacement, breakage and plasma damage at the joint due to the thermal expansion caused by the heat of a plasma, thereby preventing a lowering of sealing properties and the generation of particles.

In the first container 2 is provided a stage 5 for horizontally supporting a wafer W as a processing object. The stage 5 is supported on a cylindrical support member 4 extending upward from the center of the bottom of an exhaust chamber 11. Quartz or a ceramic material such as AlN, Al₂O₃, etc. can be used as a material for the stage 5 and the support member 4. Of these, AlN having good thermal conductivity is preferred. A resistance heating-type heater 5a is embedded in the stage 5. The heater 5a, when powered from a heater power source 6 which is, for example, a 200 V AC source, heats the stage 5 and, by the heat, heats the wafer W as a processing object. A feed line 6a, connecting the heater 5a and the heater power source 6, is provided with a filter box 45 for filtering of RF (radio frequency). The temperature of the stage 5 is measured with a not-shown thermocouple inserted into the stage 5. The heater power source 6 is controlled based on a signal from the thermocouple, so that the temperature of the wafer W can be stably controlled e.g. in the range of room temperature to 800° C.

A bias electrode 7 as a first electrode is embedded in the front surface side (above the heater 5a) of the stage 5. The electrode 7 is embedded in a region approximately corresponding to the wafer W placed on the stage 5. A conductive material, such as molybdenum or tungsten, having a thermal expansion coefficient which is equal to or near the thermal expansion coefficient of the stage material, can be used for the electrode 7. The electrode 7 is formed e.g. in a net-like shape, a grid-like shape or a spiral shape. The stage 5 is provided with a cover 8a which covers the entire surface of the stage 5. A groove or a protrusion for guiding the wafer W is provided in the upper surface of the cover 8a. An annular quartz baffle plate 8b for uniformly evacuating the processing container 1 is provided around the circumference of the stage 5. The baffle plate 8b has a plurality of holes 8c and is supported on support columns (not shown). The stage 5 is provided with wafer support pins (not shown) for raising and lowering the wafer W while supporting it. The wafer support pins are projectable and retractable with respect to the surface of the stage 5.

Sealing members 9a, 9b, 9c, e.g. O-rings, are provided at the upper and lower joints of the second container 3, so that the joints are kept in hermetic conditions. The sealing members 9a, 9b, 9c are, for example, made of a fluorine-containing rubber material, such as Kalrez (trade name of DuPont).

A circular opening 10 is formed generally centrally in the bottom wall 2a of the first chamber 2. A downwardly-projecting exhaust chamber 11 for uniformly evacuating gas from the processing container 1 is provided continuously with the bottom wall 2a and in communication with the opening 10.

The plasma oxidation processing apparatus includes a gas introduction section for introducing a processing gas into the processing container 1. The construction of the gas introduction section will now be described. As shown in the enlarged view of FIG. 2, a plurality of vertical gas supply passages 12 are provided at arbitrary locations (e.g. evenly distributed four locations) in the first container 2. The gas supply passages 12 communicate with an annular passage 13 formed in the contact area between the upper end surface of the first container 2 and the lower end surface of the second container 3. A plurality of gas passages 14, communicating with the annular passage 13, are formed in the second container 3. In the upper end of the second container 3, evenly-distributed gas introduction ports 15a are provided at a plurality of locations (e.g. 32 locations) along the inner peripheral surface, and gas introduction passages 15b extend horizontally from the gas introduction ports 15a. The gas introduction passages 15b communicate with the gas passages 14 formed vertically in the second container 3.

The annular passage 13 is formed by stepped portions, in particular a first stepped portion 18 and a second stepped portion 19 in this embodiment, in the joint between the upper end surface of the first container 2 and the lower end surface of the second container 3. The annular passage 13 extends annularly and approximately horizontally around the interior space of the processing container 1. The annular passage 13 is connected via the gas supply passages 12 to a gas supply device 16 connected to the bottom of the processing container 1. The gas supply device 16 may be connected to the side of the processing container 1. The annular passage 13 functions as a gas distribution means for supplying a processing gas to each gas passage 14 in an evenly distributed amount, and thus functions to prevent the processing gas from being supplied in a disproportionate amount to a particular gas introduction inlet 15a.

Thus, in this embodiment, when a gas is supplied from the gas supply device 16 to the gas supply section, the gas is passed through each gas supply passage 12, the annular passage 13 and each gas passage 14, and can be introduced uniformly from the 32 gas introduction ports 15a into the processing container 1 without pressure loss in piping. This enables the generation of a highly uniform plasma in the processing container 1.

The second stepped portion 19 is provided in the lower end surface of the second container 3 so that the second stepped portion 19, in combination with the first stepped portion 18 in the upper end surface of the first container 2, can form the annular passage 13. Thus, the annular passage 13 is formed by the first stepped portion 18 in the upper end surface of the first container 2 and the second stepped portion 19 in the lower end surface of the second container 3. In this embodiment the height of the second stepped portion 19 is larger than the height of the first stepped portion 18. Accordingly, in the joint where the lower end surface of the second container 3 is joined to the upper end surface of the first container 2, the protruding surface 3b of the second stepped portion 19 is in contact with the non-protruding surface 2a of the first stepped portion 18 on that side of the joint where the sealing member 9b is disposed, whereas on that side of the joint where the sealing member 9a is disposed, the non-protruding surface 3c of the second stepped portion 19 is not in contact with the protruding surface 2b of the first stepped portion 18, with a slight gap S being formed therebetween. The sealing member 9a as a second sealing member seals the gap to keep such hermeticity as not to allow leakage of gas to the outside. The sealing member 9b as a first sealing member seals the protruding surface 3b of the second stepped portion 19 and the non-protruding surface 2a of the first stepped portion 18, which are in contact with each other, to keep the processing container 1 hermetic. Because the protruding surface 3b of the second stepped portion 19 and the non-protruding surface 2a of the first stepped portion 18 are allowed to be in contact with each other, a high-frequency current return circuit is efficiently formed and an opposite electrode (lid 27 as a second electrode) has a low surface potential, and therefore the opposite electrode is unlikely to suffer from sputtering, as will be described later. The operation of the joint structure will be described later.

An exhaust pipe 23 is connected to the side wall of the exhaust chamber 11, and to the exhaust pipe 23 is connected an exhaust device 24 including a vacuum pump. By the actuation of the vacuum pump, the gas in the processing container 1 is uniformly discharged into the interior space 11a of the exhaust chamber 11, and is discharged through the exhaust pipe 23 to the outside. The processing container 1 can thus be quickly depressurized into a predetermined vacuum, e.g. 0.133 Pa.

The side wall of the first container 2 is provided with a transfer port (not shown) for transferring the wafer W into and out of the container, and a gate valve (not shown) for opening and closing the transfer port.

The processing container 1 is open at the top, and the microwave introduction section 26 can be disposed such that it hermetically closes the opening. The microwave introduction section 26 is openable and closable by means of a not-shown opening/closing mechanism.

The microwave introduction section 26 mainly comprises, in order of distance from the stage 5, a lid 27, a transmissive plate 28, a plane antenna 31 and a retardation member 33. These components are covered with a conductive cover 34 e.g. made of stainless steel, aluminum or its alloy, and are fixed by an annular retainer ring 35 to the lid 27 via a support member 36.

The lid 27 is an opposite electrode disposed opposite the electrode 7, which is a lower electrode, of the stage 5. When the microwave introduction section 26 is closed, the top of the processing container 1 and the lid 27 having an opening/closing function are sealed by the sealing member 9c and, as will be described later, the transmissive plate 28 is supported by the lid 27. A plurality of cooling water flow passages 27b are formed in the outer peripheral surface of the lid 27. This can prevent positional displacement at the joint due to the thermal expansion caused by the heat of a plasma, thereby preventing a lowering of sealing properties and the generation of particles.

The transmissive plate 28 as a dielectric plate is made of a dielectric material, for example, quartz or a ceramic material such as Al₂O₃, AlN, sapphire, SiN, or the like, and functions as a microwave introduction window for allowing microwaves to be transmitted therethrough and introducing the microwaves into a processing space in the processing container 1. The lower surface (stage 5-side surface) of the transmissive plate 28 is not necessarily flat; for example, a recess(es) or a groove(s) may be formed in the lower surface of the transmissive plate 28 in order to make microwaves uniform and form a stable plasma. An annular protruding portion 27a, protruding toward the interior space of the processing container 1, is formed in the inner peripheral surface of the lid 27, and a peripheral portion of the lower surface of the transmissive plate 28 is supported on the protruding portion 27a hermetically by means of a sealing member 29. The processing container 1 can therefore be kept hermetic when the microwave introduction section 26 is closed.

The plane antenna 31 has a disk-like shape and, above the transmissive plate 28, is locked by a peripheral portion of the cover 34. The plane antenna 31 is, for example, comprised of a copper plate, an aluminum plate, a nickel plate or a brass plate, whose surface is plated with silver or gold, and has a large number of pairs of slots 32, penetrating the plane antenna and arranged in a predetermined pattern, for radiating electromagnetic waves such as microwaves.

Each slot 32 has a long groove-like shape as shown in FIG. 3, and adjacent two slots 32 are paired typically in a letter “T” arrangement. The pairs of slots 32 are arranged in concentric circles as a whole. The length of the slots 32 and the spacing in their arrangement are determined depending on the wavelength (λg) of microwaves. For example, the slots 32 are arranged with a spacing of λg/4 to λg. In FIG. 3, the spacing between adjacent concentric lines of slots 32 is denoted by Δr. The slots 32 may have other shapes, such as a circular shape and an arch shape. The arrangement of the slots 32 is not limited to concentric circles: For example, the slots 32 may be arranged in a spiral or radial arrangement.

The retardation member 33 has a higher dielectric constant than that of vacuum, and is provided on the upper surface of the plane antenna 31. The retardation member 33 is, for example, made of quartz, a ceramic material, a fluorine-containing resin, such as polytetrafluoroethylene, or a polyimide resin. The retardation member 33 is employed in consideration of the fact that the wavelength of microwaves becomes longer in vacuum. The retardation member 33 functions to shorten the wavelength of microwaves, thereby adjusting a plasma. The plane antenna 31 and the transmissive plate 28, and the retardation member 33 and the plane antenna 31 may be in contact with or spaced apart from each other, though preferably be in contact with each other in view of a loss of microwave power.

A cooling water flow passage 34a is formed in the cover 34 so that by passing cooling water therethrough, the cover 34, the retardation member 33, the plane antenna 31, the transmissive plate 28 and the lid 27 can be cooled. This prevents deformation or breakage of these members and enables the generation of a stable plasma. The plane antenna 31 and the cover 34 are grounded.

An opening 34b is formed in the center of the upper wall of the cover 34, and a waveguide 37 is connected to the opening 34b. The other end of the waveguide 37 is connected via a matching circuit 38 to a microwave generator 39. Thus, microwaves e.g. having a frequency of 2.45 GHz, generated in the microwave generator 39, are propagated through the waveguide 37 to the plane antenna 31. Other microwave frequencies, such as 8.35 GHz and 1.98 GHz, can also be used.

The waveguide 37 is comprised of a coaxial waveguide 37a having a circular cross-section and extending upward from the opening 34b of the cover 34, and a horizontally-extending rectangular waveguide 37b connected via a mode converter 40 to the upper end of the coaxial waveguide 37a. The mode converter 40 between the rectangular waveguide 37b and the coaxial waveguide 37a functions to convert microwaves, propagating in TE mode through the rectangular waveguide 37b, into TEM mode microwaves. An inner conductor 41 extends centrally in the coaxial waveguide 37a from the mode converter 40 to the plane antenna 31. The lower end of the inner conductor 41 is connected and secured to the center of the plane antenna 31. A flat waveguide is formed by the plane antenna 31 and the cover 34. With such construction, microwaves are propagated through the inner conductor 41 of the coaxial waveguide 37a to the plane antenna 31 and then radially throughout the plane antenna 31.

A high-frequency power source 44 for bias application is connected via a feed line 42, passing through the support member 4, and a matching box (M.B.) 43 to the electrode 7 embedded in the stage 5, so that a high-frequency bias can be applied to the wafer W. As described above, the filter box 45 is provided in the feed line 6a for feeding a power from the heater power source 6 to the heater 5a. The matching box 43 and the filter box 45 are coupled and unitized via a shielding box 46 and mounted to the bottom of the exhaust chamber 11. The shielding box 46 is formed of a conductive material such as aluminum or stainless steel. A conductive plate 47 e.g. made of copper, connected to the feed line 42, is disposed in the shielding box 46 and connected to a matcher (not shown) in the matching box 43. Owing to the use of the conductive plate 47, a contact failure is unlikely to occur and, in addition, a large contact area with the feed line 42 can be taken, leading to a small current loss.

In conventional practice, the matching box 43 and the feed line 42 are connected by an exposed coaxial cable or the like, without using the shielding box 46, which entails a loss of high-frequency power in the coaxial cable. In this case, a high-frequency current path is formed which runs from the stage 5 to an opposite electrode (the lid 27, the first container 2, the second container 3, etc. can be an opposite electrode) via a plasma processing space, and returns to the earth of the high-frequency power source 44 via the second container 3 of the processing container 1, the first container 2 and then the wall of the exhaust chamber 11. In the current path, the resistance undesirably increases in proportion to the length of the coaxial cable.

A power loss likewise occurs in an exposed coaxial cable also when the filter box 45 and the feed line 6a are connected by the exposed coaxial cable. The occurrence of power loss in the coaxial cable can result in the formation of an abnormal current path in which the high-frequency current, supplied from the high-frequency power source 44 to the electrode 7, does not flow toward the lid 27 as an opposite electrode, but flows to the heater 5a and the feed line 6a. This may hinder the formation of a normal high-frequency current path (the below-described RF return path) and cause an abnormal electrical discharge.

In view of the above, in the plasma oxidation processing apparatus 100 of this embodiment, the matching box 43 and the filter box 45 are coupled and unitized via the shielding box 46 and directly connected to the bottom of the exhaust chamber 11 of the processing container 1. This can decrease the loss of the power, supplied from the high-frequency power source 44 and which is to be used for a plasma, thereby increasing the consumption efficiency of the power used for the plasma. This also enables space-saving arrangement of the relevant components.

The inner side of the lid 27 is to be exposed to a plasma generation region. If the inner surface of the lid 27 is exposure to a strong plasma, the surface will be sputtered and wear way. In view of this, as shown in the enlarged view of FIG. 2, the surface of the protruding portion 27a, which is to be exposed to a plasma, of the lid 27 of e.g. aluminum which functions as an opposite electrode for the electrode 7 of the stage 5, is coated with a protective film of a conductive material, e.g. a silicon film 48. The silicon film 48 may have either a crystalline structure, such as a polycrystalline silicon structure, or an amorphous structure. The conductive silicon film 48 efficiently forms a high-frequency current path that runs from the stage 5 to the lid 27 as an opposite electrode via a plasma processing space, thereby preventing a short circuit or an abnormal electrical discharge at other sites. In addition, the silicon film 48 protects the surface of the lid 27 from the oxidizing action and the sputtering action of a plasma, thereby preventing contamination of a wafer with the metal of the lid 27, e.g. aluminum. The silicon film 48, when oxidized by the oxidizing action of a plasma, turns into a silicon dioxide film (SiO₂ film). The silicon dioxide film is very thin, and has a small product of the dielectric constant and the resistivity. Accordingly, the silicon dioxide film can maintain the proper high-frequency current path that runs from the stage 5 to the lid 27 as an opposite electrode via a plasma processing space.

In particular, when plasma oxidation processing of a wafer W is carried out in the plasma oxidation processing apparatus 100, the silicon film 48 is oxidized by the oxidizing action of a plasma and turns into a silicon dioxide film (SiO₂ film). The dielectric constant ε of SiO₂ is 3.4, and the resistivity ρ is 7.7×10¹⁴ Ω·m; the product of the dielectric constant and the resistivity (ε×ρ) is as small as 2.3×10². With reference to metal oxides, on the other hand, the dielectric constant ε of Y₂O₃ is 12.5, and the resistivity ρ is 10×10¹⁶ Ω·m; the product of the dielectric constant and the resistivity (ε×ρ) is as large as 1.3×10³. The dielectric constant ε of Al₂O₃ is 10.8, and the resistivity ρ is 5.8×10¹⁴ Ω·m; the product of the dielectric constant and the resistivity (ε×ρ) is as large as 5.5×10². In general, the larger the product of the dielectric constant and the resistivity (ε×ρ) is, the more electric charges accumulate on the surface of the oxide film, and therefore the higher the surface potential becomes. Thus, the oxide film is more easily charged up, and therefore is more susceptible to sputtering action, leading to lower durability of the film. Further, the larger the product of the dielectric constant and the resistivity (ε×ρ) is, the more an abnormal electrical discharge is likely to occur. Though the silicon of the silicon oxide film 48 is oxidized by a plasma and turns into SiO₂, the product of the dielectric constant and the resistivity (ε×ρ) of the silicon dioxide protective film is small compared to a protective film of yttria or alumina. Accordingly, the surface potential of the silicon dioxide film is less likely to rise. The protective film can therefore maintain the durability for a long period of time and can prevent the occurrence of an abnormal electrical discharge.

For the above purposes, the silicon film 48 formed on the lid 27 preferably is a dense film having a low porosity and a low resistivity. The higher the porosity of the silicon film 48, the higher the volume resistivity. Preferably, the porosity is in the range of 1 to 10% and the volume resistivity is in the range of 5×10⁴ to 5×10⁵ Ω·cm². The thickness of the silicon film 48 is preferably in the range of 10 to 800 μm, more preferably in the range of 50 to 500 μm, and desirably in the range of 50 to 150 μm. If the thickness of the silicon film 48 is less than 10 μm, the protecting effect of the film will be insufficient. If the film thickness is more than 800 μm, cracking, peeling, etc. of the film due to stress are likely to occur.

The silicon film 48 as a protective film can be formed by a film-forming technique, such as PVD (physical vapor deposition) or CVD (chemical vapor deposition), thermal spraying, etc. Among them, thermal spraying, which is relatively inexpensive and can easily control the porosity and the volume resistivity of a silicon film in the preferred ranges, is preferred. Thermal spraying includes flame spraying, arc spraying, laser spraying, plasma spraying, etc. Among them, plasma spraying is preferred from the viewpoint of forming a high-purity film with good controllability. Plasma spraying can be exemplified by atmospheric plasma spraying and vacuum plasma spraying.

In the plasma oxidation processing apparatus 100 of this embodiment, a cylindrical liner made of quartz is provided on the inner peripheral surface of the processing container 1. The liner comprises an upper liner 49a as a first insulating plate, mainly covering the inner peripheral surface of the upper second container 3 of the processing container 1, and a lower liner 49b as a second insulating plate, connecting with the upper liner 49a and mainly covering the inner peripheral surface of the lower first container 2 of the processing container 1. The upper liner 49a and the lower liner 49b function to avoid contact between the wall and a plasma so as to prevent metal contamination caused by the constituent material of the processing container 1, and to prevent the occurrence of a short circuit or abnormal electrical discharge by which a high-frequency current flows from the stage 5 toward the wall of the processing container 1. The lower liner 49b, disposed nearer to the stage 5 at a short distance thereto, is thicker than the upper liner 49a. The thicknesses of the liners are set in consideration of the impedance and at such a thickness as not to cause a short circuit or abnormal electrical discharge of high-frequency current.

The lower liner 49b is provided such that it covers at least part of that area of the inner peripheral surfaces of the first processing container 2 and the exhaust chamber 11 which lies lower than the stage 5 in which the electrode 7 is embedded. The lower end of the lower liner 49b preferably lies at a lower position in the exhaust chamber 11. This is because the distance between the stage 5 and the first container 2 is shortest at a portion below the stage 5, and an abnormal electrical discharge at that portion should be prevented. Quartz is preferred as a material for the upper liner 49a and the lower liner 49b; however, it is possible to use other dielectric materials, e.g. a ceramic material such as Al₂O₃, AlN or Y₂O₃. The upper liner 49a and the lower liner 49b may be formed by coating (e.g. thermal spraying) with such a dielectric material.

The components of the plasma oxidation processing apparatus 100 are each connected to and controlled by the control section 50. The control section 50 typically comprises a computer and, as shown in FIG. 4, includes a process controller 51 provided with a CPU, and a user interface 52 and a storage unit 53, both connected to the process controller 51. The process controller 51 is a control means which comprehensively controls those components of the plasma oxidation processing apparatus 100 which are related to process conditions such as temperature, pressure, gas flow rate, microwave power, high-frequency power for bias application, etc. (heater power source 6, gas supply device 16, exhaust device 24, microwave generator 39, high-frequency power source 44, etc.).

The user interface 52 includes a keyboard for a process manager to perform a command input operation, etc. in order to manage the plasma oxidation processing apparatus 100, a display which visualizes and displays the operating situation of the plasma oxidation processing apparatus 100, etc. In the storage unit 53 are stored a control program (software) for executing, under control of the process controller 51, various processings to be carried out in the plasma oxidation processing apparatus 100, and a recipe in which data on processing conditions, etc. is recorded.

A desired processing is carried out in the processing container 1 of the plasma oxidation processing apparatus 100 under the control of the process controller 51 by calling up an arbitrary recipe from the storage unit 53 and causing the process controller 51 to execute the recipe, e.g. through the operation of the user interface 52 performed as necessary. With reference to the process control program and the recipe of processing condition data, etc., it is possible to use those stored in a computer-readable storage medium, such as CD-ROM, hard disk, flexible disk, flash memory, DVD, blu-ray disc, etc. or to transmit them from another device e.g. via a dedicated line.

The plasma oxidation processing apparatus 100 thus constructed enables plasma processing to be carried out at a low temperature, e.g. from room temperature (about 25° C.) to 600° C., without damage e.g. to a base film or a substrate (wafer W). Further, the plasma oxidation processing apparatus 100 is excellent in the uniformity of plasma, and can therefore achieve uniform processing even for a large diameter wafer W (processing object).

The operation of the plasma oxidation processing apparatus 100 will now be described. First, a wafer W is carried into the processing container 1 and placed on the stage 5. Processing gases, for example, a rare gas such as Ar, Kr or He, and an oxidizing gas such as O₂, N₂O, NO, NO₂ or CO₂, are supplied from the gas supply device 16 and introduced through the gas introduction ports 15a into the processing container 1 respectively at a predetermined flow rate. H₂ gas may be added to the processing gases, if necessary.

Next, microwaves from the microwave generator 39 are introduced via the matching circuit 38 into the waveguide 37. The microwaves are then passed through the rectangular waveguide 37b, the mode converter 40 and the coaxial waveguide 37a, and supplied through the inner conductor 41 to the plane antenna 31. The microwaves are then radiated from the slots 32 of the plane antenna 31, and passed through the transmissive plate 28 into the processing container 1.

The microwaves propagate in TE mode in the rectangular waveguide 37b. The TE mode microwaves are converted into TEM mode microwaves by the mode converter 40, and the TEM mode microwaves are propagated in the coaxial waveguide 37a toward the plane antenna 31. By the microwaves radiated from the slots 32 of the plane antenna 31 and introduced into the processing container 1 via the transmissive plate 28, an electromagnetic field is formed in the processing container 1, and the processing gases turn into a plasma.

Because the microwaves are radiated from the large number of slots 32 of the plane antenna 31, the plasma has a high density of about 1×10¹⁰ to 5×10¹²/cm³ and, in the vicinity of the wafer W, has a low electron temperature of not more than about 1.5 eV. Therefore, by allowing the plasma to act on the wafer W, the wafer can be processed with little plasma damage.

In this embodiment, a high-frequency power at a predetermined frequency is supplied from the high-frequency power source 44 to the electrode 7 of the stage 5 during plasma processing. The frequency of the high-frequency power supplied from the high-frequency power source 44 is preferably in the range of 100 kHz to 60 MHz, more preferably in the range of 400 kHz to 13.5 MHz. The high-frequency power supplied, in terms of the power density per unit area of the wafer W, is preferably in the range of 0.2 to 2.3 W/cm², more preferably in the range of 0.35 to 1.2 W/cm². The high-frequency power is preferably in the range of 200 to 2000 W, more preferably in the range of 300 to 1200 W. The high-frequency power supplied to the electrode 7 of the stage 5 has the effect of drawing ion species in the plasma to the wafer W while maintaining the low electron temperature of the plasma. Accordingly, by supplying a high-frequency power to the electrode 7 to thereby apply a bias to the wafer W, the plasma oxidation processing rate can be increased while preventing plasma damage to the wafer W and, in addition, the uniformity of processing in the wafer surface can be enhanced.

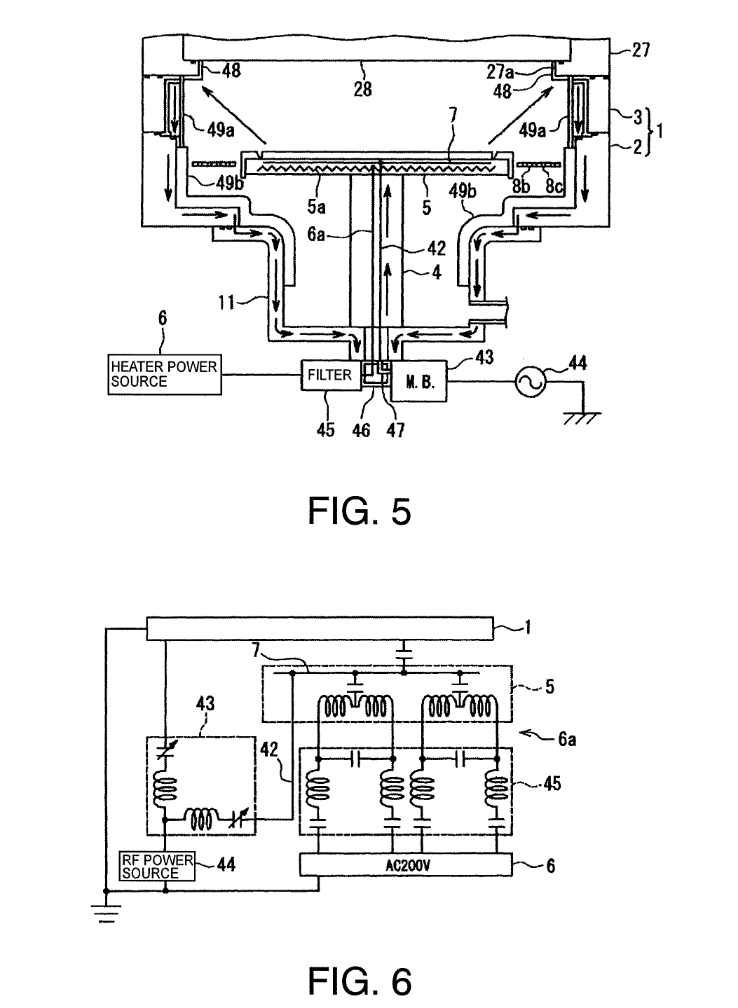

As shown by the arrows in FIG. 5, according to the return circuit construction of the present invention, a high-frequency power is supplied from the high-frequency power source 44 to the electrode 7 of the stage 5 via the unitized high-frequency power introduction section (the matching box 43 and the conductive plate 47 in the shielding box 46) and the feed line 42 with high efficiency and small power loss. The high-frequency power supplied to the electrode 7 forms a high-frequency current path (RF return circuit) that runs from the stage 5 to the lid 27 as an opposite electrode via a plasma formation space, and then to the earth of the high-frequency power source 44 via the second container 3 of the processing container 1, the first container 2 and the wall of the exhaust chamber 11. An equivalent circuit of the RF return circuit is shown in FIG. 6. In this embodiment the conductive silicon film 48 (or its oxide, SiO₂ film) is provided in the area of the lid 27 which faces a plasma generation region. This can prevent the formation of the high-frequency current path, which runs from the stage 5 to the lid 27 as an opposite electrode via a plasma processing space, from being hindered and can stably form the high-frequency current path. Furthermore, positioned adjacent to the silicon film 48, the upper liner 49a and the thicker lower liner 49b are provided on the interior surfaces of the second container 3 and the first container 2. This can securely prevent a short circuit or abnormal electrical discharge to the interior surfaces.

Though the silicon oxide film 48 is oxidized by the action of a plasma and turns into an SiO₂ film, the product of the dielectric constant and the resistivity (ε×ρ) of the silicon dioxide film is small compared to a film of yttria or alumina. Accordingly, the surface potential of the silicon dioxide film is unlikely to rise, and sputtering due to charging-up as well as an abnormal electrical discharge are unlikely to occur. The silicon dioxide film is thus excellent in the durability and can prevent metal contamination, e.g. aluminum contamination, for a long period of time. Thus, the silicon film 48 can prevent an abnormal electrical discharge and can also prevent metal contamination.

In this embodiment, as described above, in the joint between the second container 3 and the first container 2, the protruding surface 3b of the second stepped portion 19 is in contact with the non-protruding surface 2a of the first stepped portion 18 on that side of the joint where the sealing member 9b is provided, whereas on that side of the joint where the sealing member 9a is provided, the non-protruding surface 3c of the second stepped portion 19 is not in contact with the protruding surface 2b of the first stepped portion 18, with a slight gap S being formed therebetween. Due to the restrictions of machining accuracy, it is necessary to make one of the first stepped portion 18 and the second stepped portion 19 higher and bring either one of the two pairs of protruding surface and non-protruding surface, belonging to the first stepped portion 18 and the second stepped portion 19, into contact. In the processing container structure of a conventional apparatus in which no high-frequency bias power is supplied to the state 5, in order to ensure the hermeticity of the processing container 1 mainly by the sealing member 9a lying outside the annular passage 13, the protruding surface 2b of the first stepped portion 18 is in close contact with the non-protruding surface 3c of the second stepped portion 19 on that side of the joint where the sealing member 9a is provided, whereas on that side of the joint where the sealing member 9b is provided, the non-protruding surface 2a of the first stepped portion 18 is not in contact with the protruding surface 3b of the second stepped portion 19, with a gap being formed therebetween. In this case, the inner sealing member 9b mainly functions as a gas seal between the interior of the processing container 1 and the annular passage 13.

In the plasma oxidation processing apparatus 100 which supplies a high-frequency bias to the electrode 7 of the stage 5, however, the high-frequency power supplied to the electrode 7 forms a stable high-frequency current path (RF return circuit) that runs from the stage 5 to the lid 27 as an opposite electrode via a plasma formation space, and then to the earth of the high-frequency power source 44 via the second container 3 and the first container 2 of the processing container 1, and the wall of the exhaust chamber 11, as described above. In the current path, a high-frequency current travels as a surface current along the interior walls of the second container 3 and the first container 2. If a gap exists between the second container 3 and the first container 2 on their interior surface side, the current will be shut off by the gap, and the high-frequency current path will be complicated and longer. This can cause an abnormal electrical discharge e.g. at the corner of the first stepped portion 18 or the second stepped portion 19, thus hindering the formation of a proper high-frequency current path. In this embodiment, therefore, the protruding surface 3b of the second stepped portion 19 is brought into contact with the non-protruding surface 2a of the first stepped portion 18 on that side of the joint where the sealing member 9b is provided, so that a high-frequency current will flow smoothly along the interior surface of the processing container 1, i.e. the interior walls of the second container 3 and the first container 2. The contact area between the protruding surface 3b of the second stepped portion 19 and the non-protruding surface 2a of the first stepped portion 18 is designed to be small in order to obtain a large contact pressure and thereby stabilize conduction of current.

As described hereinabove, the plasma oxidation processing apparatus 100 of this embodiment makes it possible to stabilize the high-frequency current path of the high-frequency bias power supplied to the electrode 7 of the stage 5 on which a wafer W is placed, thereby enhancing the power consumption efficiency and, in addition, to prevent an abnormal electrical discharge and generate a stable plasma, thus enabling a highly efficient process.

Experiments were conducted to examine (1) aluminum contamination in plasma oxidation processing and (2) the high-frequency power dependency of the oxidation rate of the surface silicon of a wafer W and its uniformity in the wafer surface both in the case where the silicon film 48 is formed on the interior surface of the aluminum lid 27 (opposite electrode) which is to be exposed to a plasma and in the case where a conventional aluminum lid without the silicon film 48 is used. The silicon film 48 was formed by atmospheric plasma spraying at a spray thickness of 80 μm. The silicon film 48 was found to have a purity of 99.9%, a volume resistivity of 1×10⁵ Ω·cm², a porosity of about 6% and a surface roughness (Ra) of 4.86.

Plasma processing was carried out in the following manner: A processing gas containing Ar gas, O₂ gas and H₂ gas was supplied into the processing container 1 at the following flow rate ratio: Ar/O₂/H₂=1200/388/12 mL/min (sccm) [the ratio (O₂+H₂)/(Ar+O₂+H₂) is 25 vol %, the ratio H₂/(O₂+H₂) is 3 vol %] while applying a 2.45 GHz microwave power for plasma generation at 4000 W (power density 2.05 W/cm²) and keeping the interior pressure of the processing container 1 at 667 Pa. In this experiment, a high-frequency bias power, having a frequency of 13.56 MHz and a power of 600 W (power density 0.702 W/cm²), was supplied to the electrode 7 of the stage 5.

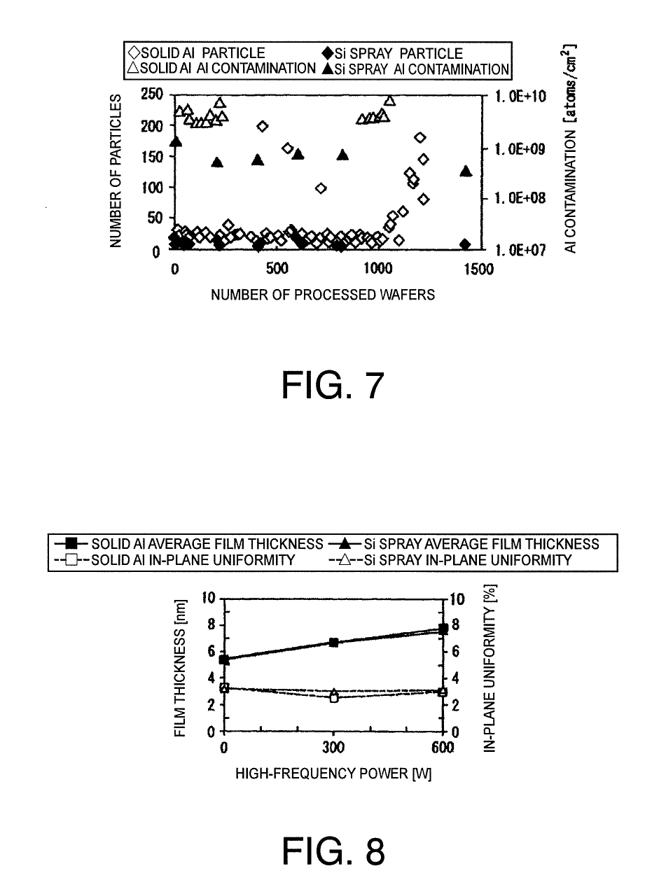

Approximately 1500 wafers W were processed under the above conditions, and aluminum contamination and the number of particles were measured. The results are shown in FIG. 7. Aluminum contamination was about 8×10⁹ to 5×10⁹ atoms/cm² in the case where the lid (of solid Al) having an exposed aluminum surface was used, whereas aluminum contamination was about 2.8×10⁹ to 5×10⁸ atoms/cm², thus less than 3×10⁹atoms/cm², in the case where the lid 27 having the silicon (Si spray) film 48 was used. The number of particles remains around 20 until the number of processed wafers W reaches about 1000, and exceeds 100 after the number of processed wafers exceeds about 1000 in the case where the lid (of solid Al) having an exposed aluminum surface was used, whereas the number of particles is as small as around 10 even after processing 1500 wafers W in the case where the lid 27 having the silicon (Si spray) film 48 was used.

Plasma oxidation processing was carried under the same conditions as in the above experiment, except that the 13.56 MHz high-frequency bias power supplied to the electrode 7 of the stage 5 was 0 W (no bias applied), 300 W or 600 W. The high-frequency power dependency of the average thickness of a silicon oxide film formed on a wafer W and its uniformity in the wafer surface was determined. The results are shown in FIG. 8. The uniformity in wafer surface was determined by dividing (the range between the maximum film thickness and the minimum film thickness) by (the average film thickness×2)×100 (%). FIG. 8 shows approximately the same changes in the oxidation rate and in the uniformity in wafer surface for the two cases. This indicates that substantially the same processing is possible even when the protective film is formed on the lid.

The present invention is not limited to the embodiments described above, but is capable of various modifications. For example, though aluminum is used as the base material for the lid 27 as a member to be exposed to a plasma, other metals such as stainless steel may also be used, and the same technical effect can be achieved. The present invention is not limited to plasma oxidation processing, but is applicable to other various types of plasma processing, such as plasma nitridation, plasma etching, etc., insofar as the process involves application of a high-frequency power to the electrode 7 of the stage 5. Further, not only a semiconductor wafer but other types of substrates, such as a glass substrate for FPD, can also be used as a processing object.

1. A plasma processing apparatus comprising:
a processing container, having an opening at a top thereof, for processing a processing object by using a plasma;
a gas introduction part that supplies a processing gas into the processing container;
an exhaust device that depressurizes and evacuates the processing container;
a stage, for placing the processing object thereon, disposed in the processing container;
a first electrode, embedded in the stage, for applying a bias to the processing object;
a second electrode comprising a conductive member and formed at a location across plasma processing space from the first electrode, at least part of the second electrode facing a plasma generation space in the processing chamber;
a dielectric plate transmissive to microwaves, supported by the second electrode and closing the opening of the processing chamber; and
a plane antenna, provided over the dielectric plate, for introducing microwaves into the processing chamber,
wherein a protective film is formed on a surface of the portion, facing the plasma generation space, of the second electrode, the protective film being made by coating the surface with a silicon film, and wherein a first insulating plate is provided along an upper portion of an interior wall of the processing container, and a second insulating plate is provided adjacent to the first insulating plate and along a lower portion of the interior wall of the processing container.

2. The plasma processing apparatus according to claim 1, wherein a thickness of the second insulating plate is larger than a thickness of the first insulating film.

3. The plasma processing apparatus according to claim 2, wherein the second insulating plate covers at least part of that area of the interior wall of the processing container which lies lower than the stage in which the first electrode is embedded.

4. The plasma processing apparatus according to claim 3, wherein the lower end of the second insulating plate lies in an exhaust chamber provided continuously with the bottom of the processing container.

5. The plasma processing apparatus according to claim 1, wherein the processing container includes a first container and a second container joined to an upper end surface of the first container; a gas passage for the processing gas, coming from a gas supply mechanism and to be supplied into the processing container, is formed between the first container and the second container; an inner first sealing member and an outer second sealing member are provided doubly on both sides of the gas passage; and the first container is in contact with the second container in an inner joint area, lying on the inner side of the processing container, where the first sealing member is provided, whereas a gap is formed between the first container and the second container in an outer joint area, lying on the outer side of the processing container, where the second sealing member is provided.

6. The plasma processing apparatus according to claim 5, wherein the gas passage is formed by a step provided in the upper end surface of the first container and by a step provided in a lower end surface of the second container.

7. The plasma processing apparatus according to claim 1, wherein said plasma processing apparatus is constructed as a plasma oxidation processing apparatus for performing plasma oxidation processing of the processing object, and wherein the protective film of silicon has been oxidized by the oxidizing action of the plasma and modified into a silicon dioxide film.

8. The plasma processing apparatus according to claim 1, wherein the dielectric plate, the first insulating plate and the second insulating plate are made of quartz.

9. The plasma processing apparatus according to claim 1, wherein the second electrode is a lid for hermetically opening and closing the processing container.

10. A plasma processing apparatus comprising:
a processing container, having an opening at a top thereof, for processing a processing object by using a plasma;
a gas introduction part that supplies a processing gas into the processing container;
an exhaust device that depressurizes and evacuates the processing container;
a stage, for placing the processing object thereon, disposed in the processing container;
a first electrode, embedded in the stage, for applying a bias to the processing object;
a second electrode comprising a conductive member and formed at a location across plasma processing space from the first electrode, at least part of the second electrode facing a plasma generation space in the processing chamber;
a dielectric plate transmissive to microwaves, supported by the second electrode and closing the opening of the processing chamber;
a plane antenna, provided over the dielectric plate, for introducing microwaves into the processing chamber;
a first insulating plate provided along an upper portion of an interior wall of the processing container; and
a second insulating plate provided adjacent to the first insulating plate and along a lower portion of the interior wall of the processing container,
wherein a thickness of the second insulating plate is larger than a thickness of the first insulating film.

11. The plasma processing apparatus according to claim 10, wherein the second insulating plate covers at least part of that area of the interior wall of the processing container which lies lower than the stage in which the first electrode is embedded.

12. The plasma processing apparatus according to claim 11, wherein the lower end of the second insulating plate lies in an exhaust chamber provided continuously with the bottom of the processing container.

13. The plasma processing apparatus according to claim 10, wherein the processing container includes a first container and a second container joined to an upper end surface of the first container; a gas passage for the processing gas, coming from a gas supply mechanism and to be supplied into the processing container, is formed between the first container and the second container; an inner first sealing member and an outer second sealing member are provided doubly on both sides of the gas passage; and the first container is in contact with the second container in an inner joint area, lying on the inner side of the processing container, where the first sealing member is provided, whereas a gap is formed between the first container and the second container in an outer joint area, lying on the outer side of the processing container, where the second sealing member is provided.

14. The plasma processing apparatus according to claim 10, wherein the gas passage is formed by a step provided in the upper end surface of the first container and by a step provided in a lower end surface of the second container.

15. The plasma processing apparatus according to claim 10, wherein the dielectric plate, the first insulating plate and the second insulating plate are made of quartz.

16. A plasma processing apparatus comprising:
a processing container, having an opening at a top thereof, for processing a processing object by using a plasma;
a gas introduction part that supplies a processing gas into the processing container;
an exhaust device that depressurizes and evacuates the processing container;
a stage, for placing the processing object thereon, disposed in the processing container;
a first electrode, embedded in the stage, for applying a bias to the processing object;
a second electrode comprising a conductive member and formed at a location across plasma processing space from the first electrode, at least part of the second electrode facing a plasma generation space in the processing chamber;
a dielectric plate transmissive to microwaves, supported by the second electrode and closing the opening of the processing chamber;
a plane antenna, provided over the dielectric plate, for introducing microwaves into the processing chamber;
a first insulating plate provided along an upper portion of an interior wall of the processing container; and
a second insulating plate provided adjacent to the first insulating plate and along a lower portion of the interior wall of the processing container,
wherein the processing container includes a first container and a second container joined to an upper end surface of the first container; a gas passage for the processing gas, coming from a gas supply mechanism and to be supplied into the processing container, is formed between the first container and the second container; an inner first sealing member and an outer second sealing member are provided doubly on both sides of the gas passage; and the first container is in contact with the second container in an inner joint area, lying on the inner side of the processing container, where the first sealing member is provided, whereas a gap is formed between the first container and the second container in an outer joint area, lying on the outer side of the processing container, where the second sealing member is provided.

17. The plasma processing apparatus according to claim 16, wherein the second insulating plate covers at least part of that area of the interior wall of the processing container which lies lower than the stage in which the first electrode is embedded.

18. The plasma processing apparatus according to claim 17, wherein the lower end of the second insulating plate lies in an exhaust chamber provided continuously with the bottom of the processing container.

19. The plasma processing apparatus according to claim 16, wherein the gas passage is formed by a step provided in the upper end surface of the first container and by a step provided in a lower end surface of the second container.
